(19) United States
(12) Patent Application Publication
(10) Pub. No.: US 2017/0087626 A1
(43) Pub. Date: Mar. 30, 2017

(54) INVESTMENT-DIECASTING MOLD

(71) Applicant: Crucible Intellectual Property, LLC, Rancho Santa Margarita, CA (US)

(72) Inventor: Adam A. Verreault, Dove Canyon, CA (US)

(21) Appl. No.: 15/280,972

(22) Filed: Sep. 29, 2016

Related U.S. Application Data
(60) Provisional application No. 62/235,115, filed on Sep. 30, 2015.

(51) Int. Cl. B22D 17/08; B22C 9/22; B22C 1/00; B22C 3/00; B22C 7/02; B22D 17/20; B22D 21/00; C22F 1/00; C22C 45/02; C22C 45/10; C22C 45/04; H05K 5/00; H05K 5/03; H04B 1/3888; H04M 1/02; B22C 9/04

(52) U.S. Cl. CPC B22D 17/08; B22C 9/04; B22C 9/22; B22C 1/00; B22C 3/00; B22C 7/02; B22D 17/2015; B22D 21/005; C22F 1/002; C22C 45/02; C22C 45/10; C22C 45/04; H05K 5/0017; H05K 5/03; H04B 1/3888; H04M 1/0202

(57) ABSTRACT

An investment-diecasting mold has a thin inner investment casting ceramic layer surrounded by a thicker outer metallic diecasting material. The two layers, inner ceramic and outer metallic, provide a hybrid mold for the fabrication of near-to-net or near net shape amorphous alloy composed parts. The inner ceramic layer being appropriate for thermoconductivity and the casting of intricately designed parts, and the outer metallic diecasting mold for support of the inner investment casting layer and as a heat sink for quench of the molten amorphous alloys during use.

### CROSS-REFERENCE TO RELATED APPLICATION(S)

This application is a non-provisional patent application of U.S. Provisional Patent Application No. 62/235,115, filed Sep. 30, 2015 and titled “INVESTMENT DIECASTING MOLD,” the disclosure of which is herein by reference in its entirety.

### FIELD

The disclosure relates generally to molds and processes of using molds to create amorphous metal parts. In particular, the disclosure provides a hybrid mold and molding process that combines the benefits of investment casting with the functional parameters of diecast molding.

### BACKGROUND

Investment casting is a technique for making complex near-to-net or near net shaped parts where the mold is formed around a pattern of wax. Investment casting is often utilized to produce metallic parts having complicated shapes or geometries, often where the shape or geometry is problematic using a diecasting technique.

Amorphous metals are a family of high strength and hardness alloys that provide a number of useful properties. In particular, for example, amorphous alloys display excellent strength-to-weight ratios, resistance to corrosion, environmental durability, as well as high elastic strain limits that approach 2.0% (much higher than other non-amorphous metallic alloys).

Amorphous alloys maintain optimal utility when the alloy exhibits substantially non-crystalline structure. However, manipulation of these alloys in the absence of crystal formation is difficult and requires melted materials to be cooled at a high cooling rate. These cooling rates are not practical for fabrication using investment casting. As such, amorphous alloy composed parts are typically prepared via diecast molding techniques.

Diecasting is a process characterized by injecting molten metal under pressure and vacuum into a mold cavity. Typical mold cavities are formed from steel or other like material and require significant capital costs. Diecasting, however, is limited to less complex part designs and, where amorphous metals are concerned, less mold durability (a significant cost in fabricating amorphous metal parts). Further, where parts made of amorphous metal are concerned, excessive post molding modification is often required, for example, stock may be added to the amorphous metal part which is then removed by machining and polishing. In the end it is very difficult to fabricate near-to-net shaped parts using diecasting where amorphous alloys are concerned.

The present disclosure is provided to overcome the limitations of investment casting, and of die-casting, parts composed of amorphous metals.

### SUMMARY

A hybrid investment-diecasting mold for fabrication of amorphous alloy parts is described herein. Hybrid investment diecasting molds in accordance with embodiments herein include a thin inner layer useful in investment casting and a thicker outer layer useful in diecasting, the two layers functioning together to form the hybrid mold.

Inner investment casting materials are typically composed of thermal-conductive ceramics such as alumina, silicon, nitride, silicon nitride, and the like, or lower conductivity ceramics like silica or zirconia. This layer provides a mold for investment casting amorphous alloys.

Outer diecasting mold materials typically have high heat capacity and thermal conductivity so as to act as a heat sink during use, and include materials like steel, stainless steel, aluminum, copper and brass. The outer diecasting mold supports the inner investment casting material and acts as a heat sink for the molten amorphous alloy to properly quench.

The hybrid investment-diecasting mold as described herein is integrated with the use of a diecasting machine where the molten amorphous alloy may be injected, under vacuum, to the cavity formed in the hybrid mold. Dissolution of the inner investment layer from the properly quenched amorphous alloy composed part provides a net-to-shape part that requires little or no post fabrication processing.

Methods of part fabrication in accordance with the investment-diecasting mold are also provided herein. A wax print is prepared from a desired part and positioned in an outer diecasting mold leaving a gap between the wax print and outer diecasting mold assembly. Using the appropriate filling conduit, the gap is filled with the appropriate investment ceramic material to prepare a thin, typically about 1 mm to 4 mm thick, investment casting layer on the wax print. After removal of the wax print from the investment diecasting mold, the mold is placed in a diecasting machine and molten amorphous alloy injected. The amorphous alloy part is quenched and the investment diecasting mold removed from its surface. Vibration or pressure wash can be used to dislodge the near-to-net or near net shape amorphous alloy part from the investment diecasting mold. Where appropriate the part can undergo further processing.

In one embodiment, an investment-diecasting mold is described. The investment-diecasting mold has an inner investment casting mold for defining a cavity. The cavity is shaped as a negative imprint for at least a portion of a part. The investment-diecasting mold also has an outer diecasting mold which encases and operatively contacts the inner investment mold.

In some aspects, the inner investment casting mold is composed of a thermally conductive ceramic material, and in some cases, is composed of alumina, silicon, nitride or silicon nitride. In other aspects, the investment casting mold has a thickness of from about 1 mm to about 4 mm.

In other aspects, the outer diecasting mold is composed of a material like steel, aluminum, copper or brass. The outer diecasting mold can have an appropriate mass to act as a heat sink for quenching parts, particularly parts made from amorphous alloy. It is also envisioned that the outer diecasting mold can define one or more cooling conduits for inclusion of water, brine, NaOH or oil.

Another embodiment herein is a method comprising filing a gap formed between a wax print and an outer diecasting mold with an investment casting material; dissolving the wax print such that it leaves a cavity formed by the investment casting material; and injecting molten amorphous alloy into the cavity formed in the investment casting material, thereby forming a desired part out of amorphous alloy in the shape of the wax print. The investment casting material can be dissolved from the part, which is then removed from the diecasting mold.

In some aspects, the method further comprises processing the amorphous alloy part after removal from the outer diecasting mold. The outer diecasting mold should have a sufficient mass and thermal conductivity to quench the desired part, and in some cases, can include cooling conduits for passing a fluid through to quench the desired part.

In other aspects, the method is directed at forming a housing for an electronic device, and in particular, a housing for a mobile phone.

Embodiments also include electronic device, particularly handheld electronic device. Electronic device comprise a housing composed of amorphous alloy, a display positioned within the housing and a cover positioned over the display. The amorphous alloy housing is at least 0.1 mm in thickness and formed to a near-to-net or near net shape by investment-diecasting.

In some aspects, the investment-diecasting is performed with an investment-diecasting mold, and the mold has an inner investment casting mold for defining a cavity, where the cavity is shaped as a negative imprint for the housing; and an outer diecasting mold, where the outer diecasting mold encases and operatively contacts the inner investment casting mold.

In other aspects, the housing is formed of a BMG and the housing is at least 0.5 mm thick. The electronic device can be a wearable electronic device or it can be a mobile phone.

### BRIEF DESCRIPTION OF THE DRAWINGS

The disclosure will be readily understood by the following detailed description in conjunction with the accompanying drawings, wherein like reference numerals designate like structural elements, and in which:

FIG. 1A is a perspective view of a desired part having an undercut and involving intricate geometries.

FIG. 1B is a perspective view of a wax print of the part illustrated in FIG. 1A.

FIG. 2A is a cross-sectional view of an outer diecasting mold.

FIG. 2B is a perspective view of the bottom half of the outer diecasting mold.

FIG. 2C is an isometric view (top) and top view (bottom) of the top half of an outer diecasting mold.

FIG. 3 is a cross-sectional view of the wax print positioned in the outer diecasting mold where a gap is defined between the inner surface of the outer diecasting mold the wax print.

FIG. 4 is a cross-sectional view of the two layers of the investment-diecasting mold (outer diecasting and inner investment) in position on a wax print.

FIG. 5 is a cross-sectional view of the mold in FIG. 4 after the wax print has been removed via steam or solvent leaving a negative cavity for amorphous alloy fabrication.

FIG. 6 is a illustrative perspective view of an investment-diecasting mold ready for loading into a diecasting machine.

FIG. 7A is a bottom view of an investment-diecasting mold filled with amorphous metal.

FIG. 7B is a cross-sectional view of the investment-diecasting mold of FIG. 7A.

FIG. 8A is a cross-sectional view of an investment-diecasting machine just prior to injection of amorphous alloy into an investment-diecasting mold.

FIG. 8B is a cross-sectional view of an investment diecasting machine after injection of amorphous alloy into an investment-diecasting mold.

FIG. 9 shows a cross-sectional view of the amorphous alloy filled investment-diecasting mold.

FIG. 10 shows a perspective view of part removal from an investment-diecasting mold.

FIG. 11 is a cross-sectional view of part extraction from an investment-diecasting mold.

FIG. 12 is a flow diagram for fabricating an amorphous alloy part in accordance with embodiments herein.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

The following disclosure relates generally to hybrid, investment-diecasting molds, and to the use of investment-diecasting molds in the creation of amorphous metal composed parts. Embodiments in accordance with the present disclosure combine the benefits of investment casting with the utility of a diecasting machine for fabrication of near-to-net shape amorphous alloy parts.

Embodiments herein utilize the benefit of investment casting, allowing for complex part geometries, including undercuts, with the durability, injection parameters, and thermal conductivity of molds in a diecasting machine. This unique combination of investment casting and diecasting allows for near-to-net or near net shaped amorphous alloy part production, a process not possible using either technique alone. In some aspects, the ability to form a near net shaped part includes parts that have geometric shapes and geometric overhangs. Conventional part fabrication often requires molding a part and post process machining geometric overhangs or openings. These overhangs can require adhering the overhang onto the part in some cases. In other aspects, the post processing not required in embodiments herein can introduce defects into the part due to removal of material or modifications of material not required by the investment-diecasted part.

Embodiments include investment-diecasting molds fabricated of an inner investment casting material and an outer thermally conductive material appropriate for diecasting. In some aspects the inner investment casting material is a layer made of a ceramic shell, while an outer diecasting layer is a mold made of materials having sufficient heat capacity and thermal conductivity to quench the inner ceramic shell during use with amorphous alloys.

The term “investment-diecasting mold” refers to the combination of an inner and outer layer of materials, where the combination allows for high pressure injection, under vacuum, of molten amorphous alloy using a metal piston. In some embodiments the investment-diecasting mold is used at room temperature, or more typically used at below room temperatures, and the resultant amorphous alloy part is prepared at a near-to-net shape.

Compositions of the inner investment casting ceramic shell may include castable variants, or powder with binder, of a high thermally conductive ceramic, for example, alumina, silicon nitride, sialon, silicon carbide, aluminum nitride, tungsten carbide, boron nitride, graphite or combinations thereof. Embodiments herein may also be composed of a lower conductivity ceramic, whether castable, or powder mixed with binder, for example, silica or zirconia (depending on thickness).

Embodiments may also include a high thermal conductivity metal/ceramic powder mixed with a suitable binder to form a high thermal conductivity paint or paste. Example metals in such paints or pastes include copper, aluminum, brass, zinc, steel, stainless steel, nickel, chromium, tungsten, silver, or combinations thereof. Example binders for use in paints or paste embodiments include: sodium silicate, potassium silicate, aluminum phosphate, silica aluminum phosphate, silica, alumina and combinations thereof.

In typical embodiments the inner investment layer is between about 0.5 mm in thickness and about 5 mm in thickness. In other embodiments the inner investment layer is between about 1 mm in thickness and about 4 mm in thickness.

In one typical embodiment, the inner investment casting ceramic shell is composed of a castable alumina cement, in another typical embodiment the inner ceramic shell is composed of aluminum powder mixed with sodium silicate.

Compositions of the outer mold, necessary for diecasting processes (for example, necessary such that the inner shell does not fail (explode) when filled with molten amorphous metal at high pressure) require sufficient heat capacity and thermal conductivity to act as a heat-sink and thereby quench the inner investment casting shell when in use with amorphous metal. Possible outer mold materials include: steel, stainless steel, aluminum, copper, or brass.

Embodiments herein also include fabrication processes or methods for producing parts composed of amorphous metal. Fabrication processes allow for the production of near-to-net shape parts which require limited post-fabrication machining.

An “amorphous alloy” is an alloy having an amorphous content of more than 50% by volume, typically more than 90% by volume and most typically more than 95% by volume. In some aspects an amorphous alloy can have an amorphous content of about 99% or more and up to about 100% by volume. Note that, amorphous by volume means to exhibit a disorderly atomic scale or arrangement as compared to most metals, which are highly ordered in atomic structure. Materials in which such a disordered structure is produced directly from the liquid state during cooling are often referred to as “glasses,” hence the name bulk metallic glasses (BMG), see below. There are additional ways besides rapid cooling to produce amorphous metals, including physical vapor deposition and melt spinning. Regardless, amorphous alloys are considered to be a class of materials and will be treated as such throughout this disclosure.

In one embodiment, amorphous alloys can be described as (Nr, Ti)ₐ(Ni, Cu, Fe)_{b}(Be, Al, Si, B)_{c}, where “a” is in the range of from about 30 to about 75 atomic percent, “b” is in the range of from about 5 to 60 atomic percent, and “c” is from about 0 to about 50 atomic percent. In addition, these amorphous alloys can accommodate substantial amounts of other transition metals, including but not limited to Nb, Cr, V, and Co.

In addition, amorphous alloys can also be described as ferrous metal based materials, for example including Fe, Ni, or Co. Exemplary compositions of such compositions include Fe₇₂Al₅Ga₂P₁₁C₆B₄. Another illustrative composition is Fe₇₂Al₇Zr₁₀Mo₅W₂B₁₅.

Other embodiments include amorphous alloys composed of zinc and titanium. These amorphous alloy compositions tend to exhibit high strength and hardness. For example, Zr and Ti-based amorphous alloys typically have yield strengths of 250 ksi or higher and hardness values of 450 Vickers or higher. Typical amorphous alloy compositions herein also have high elastic strain limits that approach up to 2.0%.

As noted above, one class of amorphous alloys are BMG. BMG is a class of metallic materials that may be solidified and cooled at relatively slow rates, and retain their amorphous, non-crystalline state at room temperature. If the cooling rate of an amorphous alloy is not sufficient, termed the critical cooling rate, crystals may form inside the alloy, so that the benefits of the amorphous state can be lost. As such, one challenge to fabrication of BMG parts is partial crystallization in the BMG during the cooling process.

Crystal formation in an amorphous alloy provides a level of uncertainty to the quality of parts formed therefrom, uncertainty that can translate to increased costs and failure rates for parts fabricated from BMG alone. In order to obtain a cooling rate equal to or above the critical cooling rate, heat is extracted from the BMG itself. As such, the thickness of a BMG material is often a limiting factor on whether the critical cooling rate may be ascertained. The thickness of BMG, for a particular fabricating technique, that aligns with the critical cooling rate is termed the critical thickness.

BMGs do not experience a liquid/solid crystallization transformation upon cooling, as with conventional metals. Rather, the highly fluid, non-crystalline form of the metal found at high temperatures (near a melting temperature Tm) becomes more viscous as the temperature is reduced (near a Tg), eventually taking on the outward physical properties of conventional solids.

Although there is no liquid/crystallization transformation for a BMG, a “melting temperature” Tm may be defined as the thermodynamic liquidus temperature of the corresponding crystalline phase. The viscosity of the BMG at the melting temperature could lie in the range of about 0.1 poise (or lower) to about 10,000 poise. The cooling rate of the molten metal to form a BMG part, for example, is typically such that the time-temperature profile during cooling does not traverse through a crystallized region in a TTT diagram. The crystallization temperature Tx is where crystallization is most rapid and occurs in the shortest time scale.

The supercooled liquid region, which is the temperature region between Tg and Tx, is a manifestation of the extraordinary stability against crystallization of BMGs. In this temperature region the BMG can exist as a high viscosity liquid. The viscosity of the BMG in the supercooled liquid region can vary between 10¹² Pas at the glass transition temperature down to 10⁵ Pas at the crystallization temperature, the high temperature limit of the supercooled liquid region. Liquids with such viscosities can undergo substantial plastic strain under an applied pressure.

Other amorphous alloy metals are known as described in U.S. Pat. No. 9,057,120, 9,103,009, 9,056,353, and 9,044,805, each of which is incorporated by reference for all purposes.

As noted above, a significant problem for the production and use of most amorphous alloys is crystal formation. Crystallization of amorphous alloys can have detrimental effects on the materials properties, particularly where toughness and strength are necessitated. Crystal formation is typically related to the amorphous alloy cooling rate, where an insufficient cooling rate often results in some amount of crystal formation.

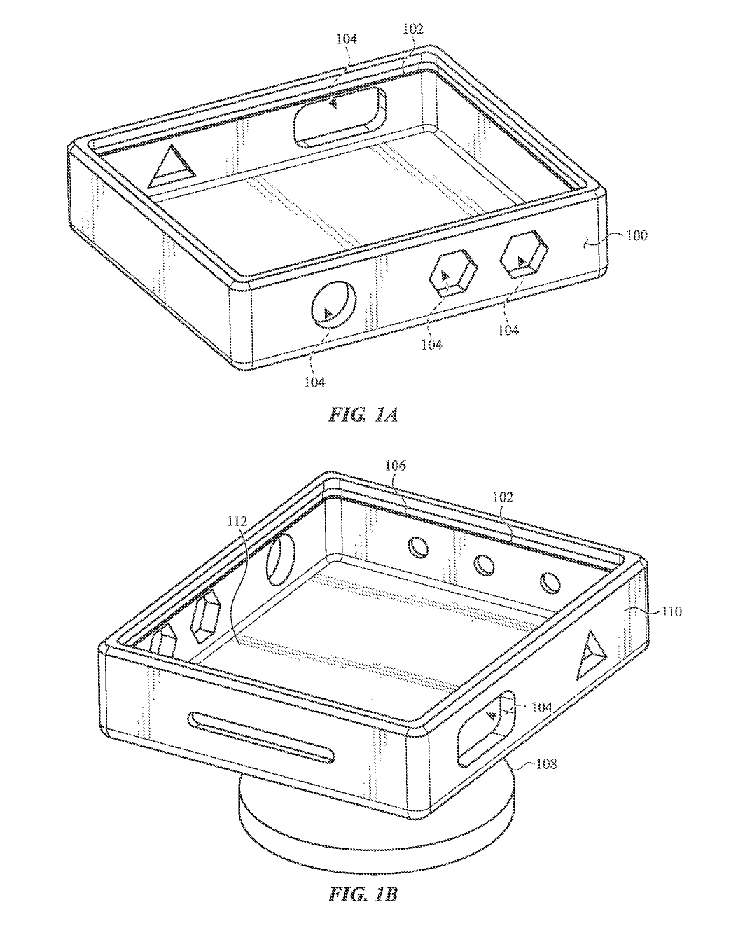

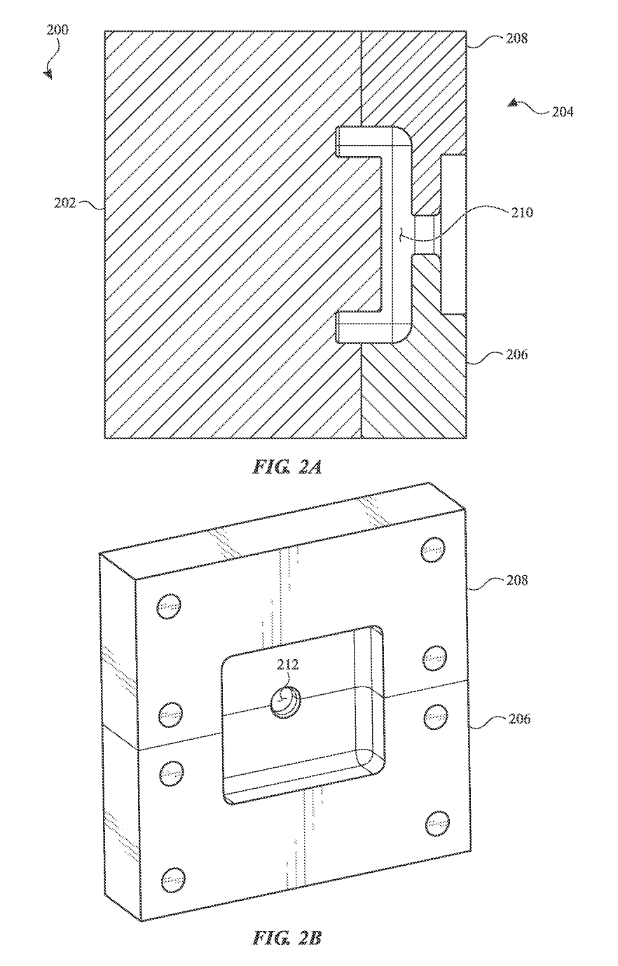

Embodiments herein are described in greater detail with reference to FIGS. 1-11.

FIG. 1A is a perspective view of a desired part 100. Although not dispositive of the type of part that benefit from embodiments of the present disclosure, part 100, made of an amorphous alloy, exhibit undercuts 102 and geometric cut-outs 104 that would prove problematic under conventional molding techniques. For example, diecasting part 100 would result in problematic issues with formation of the undercut and the geometric cut-out shapes. The desired part as shown in FIG. 1A will be used throughout the disclosure to illustrate a part for use in describing embodiments herein. However, embodiments of the hybrid investment-diecasting mold, as described herein, are appropriate for the fabrication any part shape regardless of complexity and shape. The ability to form complex near-to-net shaped parts out of amorphous alloy is a significant benefit of embodiments herein.

In one embodiment herein, the desired part can be used in the fabrication of electronic devices and/or articles integrated in electronic devices. Embodiments herein provide the amorphous alloy or BMG near-to-net shaped parts integral to electronic devices.

An electronic device herein can refer to any electronic device known in the art, for example, mobile telephone, smart phone, computer, electronic e-mail sending or receiving device, health-monitoring device, wearable electronic device, DVD player, Blue-Ray disc player, video game console, and the like. Electronic devices or articles integrated into an electronic device can also refer to a display, TV monitor, book-reader, web-browser, computer monitor, and the like or to accessories such as casings, laptop housings, smart phone housings, laptop track pads, keyboard, mouse, speakers, etc.

In one embodiment, a portable electronic device can include a cover sheet and an enclosure or housing made of the BMG formed parts described herein. The cover sheet can be composed of a polished glass, sapphire or other hardened transparent material. The housing and cover sheet come together to form an interior volume configured to enclose the various electronic components of the device. For example, the housing may define an opening in which a display is positioned. The cover sheet is positioned over the display and forms a portion of the exterior of the device. The display may include a liquid crystal device (LCD), or organic light-emitting diode (OLED) display, or other suitable display elements or components.

In accordance with embodiments herein, the housing may be formed from BMG as described herein. The housing embodiments may be of a thickness above 0.1 mm, and more typically above 0.5 mm.

As shown in FIG. 1B, a wax print 106 is prepared from part 100. The wax print can be prepared using 3D printing or other like methodology. The wax print has substantially the same or identical dimensions as the part. A wax print can be developed for any part, as long as the 3D printing, or other technology, can accommodate the contoured shape and design. A base 108 having a neck (not shown in this figure, but 109) for wax print 106 manipulation in the investment-die-casting embodiments is shown. Note that the wax print 106 includes the overhang 102 and unique geometries 104 of part 100. The was print 106 has defined side-walls 110 extending from a flat bottom piece 112.

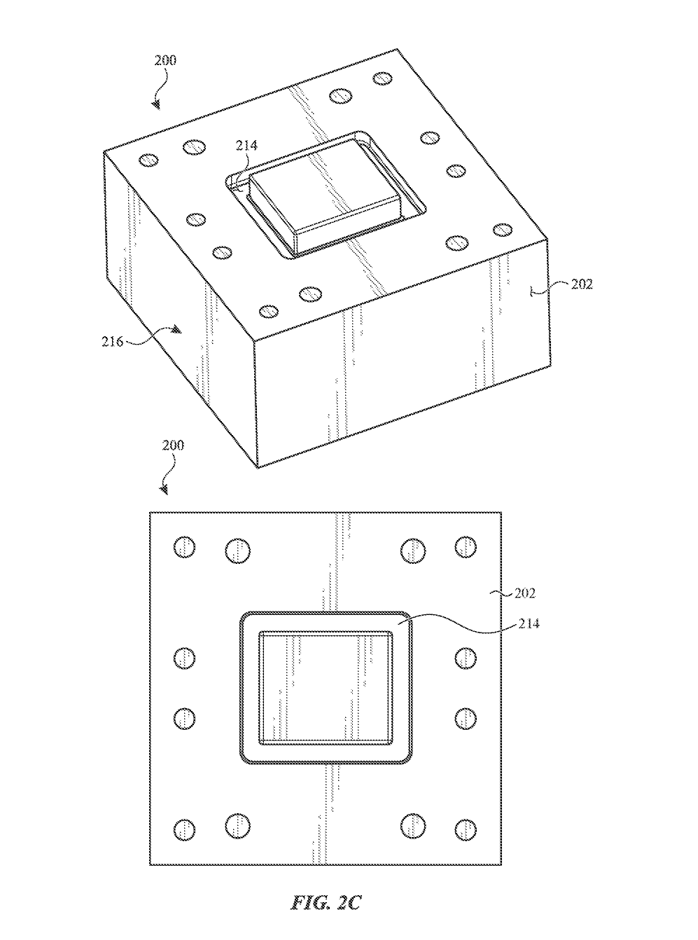

FIG. 2A shows an illustrative cross sectional view of an investment-diecasting outer mold assembly 200 in accordance with embodiments described herein. The outer mold assembly 200 in accordance with fabricating part 100 has a top outer mold 202 and a bottom outer mold 204 (the bottom outer mold be formed by two pieces 206 and 208). The combination of outer mold pieces 202, 204 and 206 have been machined to define a cavity 210 of sufficient dimensions to encase wax print 106 when appropriately positioned within.

FIG. 2B shows a schematic view of the bottom outer mold pieces, 206 and 208. The fitting of the two bottom outer mold pieces defines an opening 212 for the neck 109 of the wax print 106.

FIG. 2C shows a schematic of the top outer mold piece 202. Note that the top outer mold piece 202 has a groove 214 to capture the wax print side walls 110. Also note that the top outer mold piece groove width is sufficient to fit both the wax print and inner investment layer, as is discussed in greater detail below. The negative imprint of wax print 106 is formed by the enclosure of the top and bottom mold pieces.

The outer diecasting molds, in accordance with the disclosure, often include significant mass (arrow 216) to act as a heat sink for maintaining an appropriate cooling rate for amorphous metal during operation of the investment-diecasting mold. The mass of the outer mold is determined by the size of the amorphous metal part to be formed, the composition of the amorphous alloy, and the required cooling rate of the amount and thickness of the amorphous alloy. Generally, the mold is of sufficient uniform mass around the part to allow for a uniform cooling rate.

Compositions of the outer mold, require sufficient mass, but also require a material that has sufficient heat capacity and thermal conductivity to act as a heat-sink and thereby quench the inner investment casting shell when in use with embodiments herein, for example, parts composed of amorphous metal. Possible outer mold materials include: steel, stainless steel, aluminum, copper, or brass.

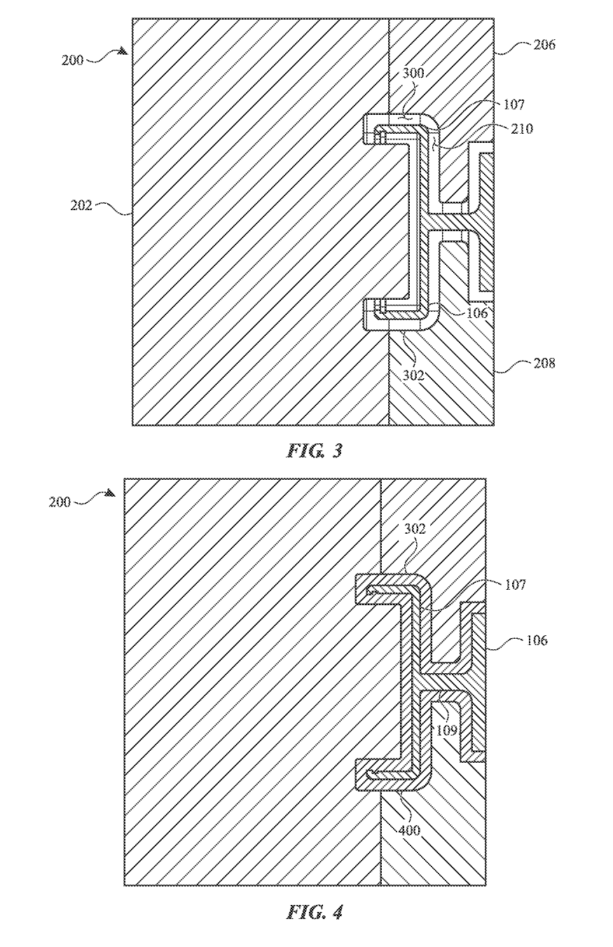

FIG. 3 is a cross-sectional view of an investment-diecasting mold in accordance with the present disclosure. The outer mold assembly 200 defines a cavity 210 between top mold piece 202 and bottom outer mold pieces 206, 208, within which the target wax print sits. The mold provides a negative imprint of the desired wax print.

As noted above, investment-diecasting molds of the present disclosure have a thin, typically between about 0.5 mm and about 5 mm, and in some cases between about 0.5 mm and about 4 mm, and most typically between about 1 mm and 4 mm, gap 300 between an outer surface 107 of the target wax print 106 (when in the mold) and the inner surface 302 of the outer mold assembly 200. Although not shown, this gap can be of uniform thickness or variable thickness as is discussed more thoroughly below. In addition, although some portion of the investment-diecasting mold always includes the gap, the gap does not have to be created between the entirety of the wax part and inner surface of the outer mold. As such, embodiments herein include any number of aspects where the gap exists between the entire wax part and the inner wall of the outer mold to very discrete areas between the wax print outer surface and inner surface of the outer mold. The gap will act as the formation site for the inner or investment layer that is created between the outer mold and the wax part.

FIG. 4 is a cross-sectional view of an investment-diecasting mold of the present disclosure where the gap between the wax part surface 107 and the inner wall 302 of the outer mold is filled with an inner investment casting material. Once set, the inner investment casting material forms the inner investment layer 400. As discussed above, inner investment casting material can include ceramics like alumina, silicon nitride, sialon, graphite, silica, zirconia, and thermally conductive pastes. Although not shown, a flange on the wax print neck 109 or other extrusion can be designed to maintain the wax print in the gap 300 (see FIG. 3) prior to addition of the inner investment casting material. Once the gap is filled with the inner investment casting material, the completed investment diecasting mold of the invention is prepared exhibiting both an outer diecasting mold and inner investment casting mold (the combination referred to as an investment-diecasting mold).

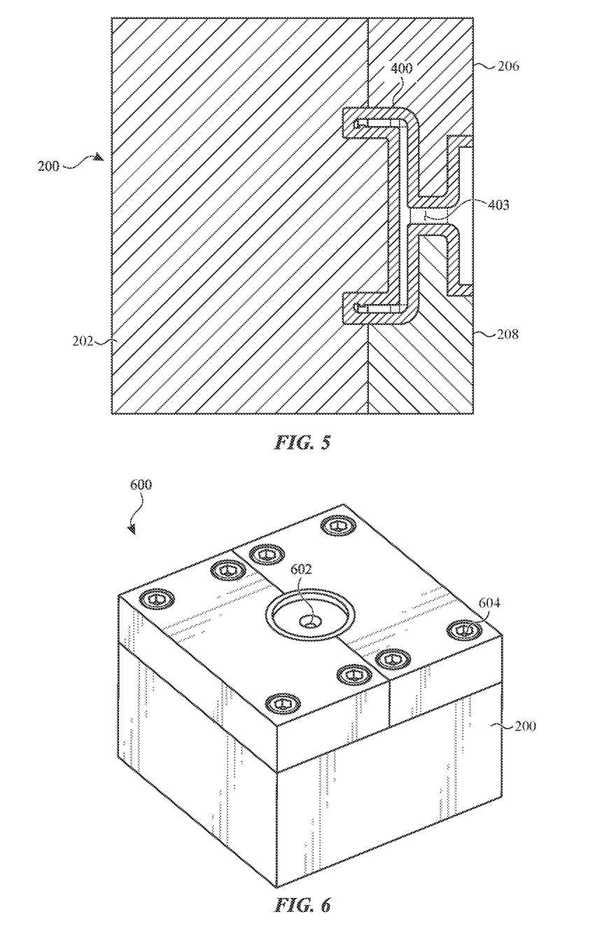

Once the investment-diecasting mold is established, the wax print 106 is removed using steam heat or solvent (see FIG. 5), providing a negative print or cavity 403. The cavity 403 being the shape and dimensions of the wax print for forming the part 100.

An amorphous alloy part 100 may now be fabricated using the precision and detail of the inner investment casting mold having the heat sink and cooling capacity of the outer diecasting mold.

FIG. 6 shows a perspective view of a closed investment-diecasting mold 600, having one possible fill opening 602 for amorphous alloy fill. Outer mold assembly 200 encases the inner investment mold and is capable of forming the amorphous alloy part 100. The outer mold assembly can be secured in any number of ways, including bolts 604.

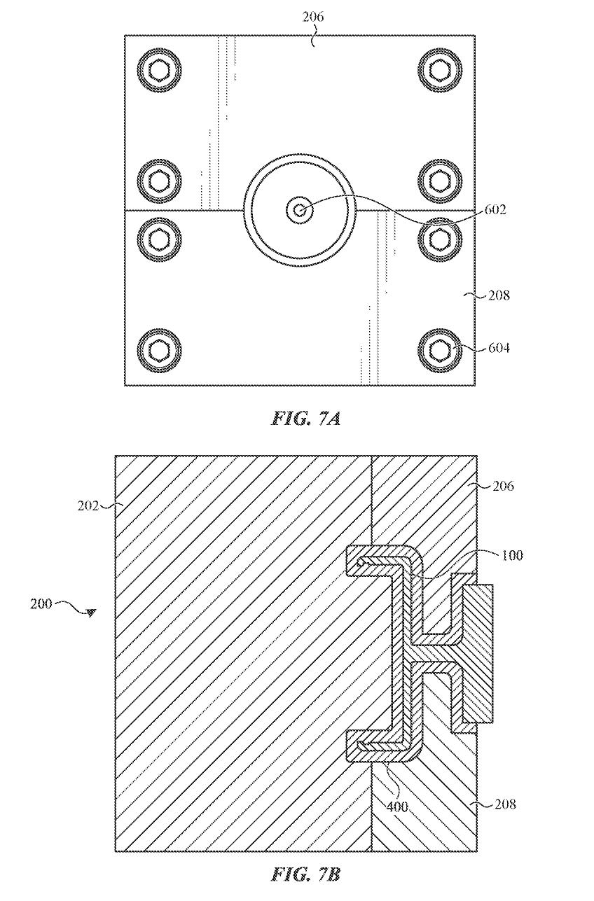

FIG. 7A shows a schematic of the same mold in FIG. 6 from a bottom view after amorphous metal filling. Note that other filling orientations are within the scope of the present disclosure. The amorphous metal can be melted to the alloys Tm in any number of know ways. Once molten, the alloy is inserted through opening 602.

FIG. 7B shows a cross-sectional view of the investment-diecasting mold in accordance with embodiment herein where the mold cavity has been filled with amorphous alloy to fabricate the part 100. As is apparent from FIG. 7B, the investment-diecasting mold provides an outer mold 202, 206, 208 acting as a heat sink for quenching the amorphous alloy and as support for the investment cast 400.

Still referring to FIG. 7B, the inner investment cast 400 is shown as a uniformly thick layer between the quenched amorphous metal part 100 and the outer diecast mold assembly 200. The inner investment mold 400 acts to protect the outer mold assembly 200 from damage by the molten amorphous metal, allows for intricate near-to-net shape part design, e.g., intricate geometries and cutouts, and thermally conducts the heat from the molten amorphous alloy to the outer diecasting mold thereby limiting crystal formation in the cooling amorphous alloy.

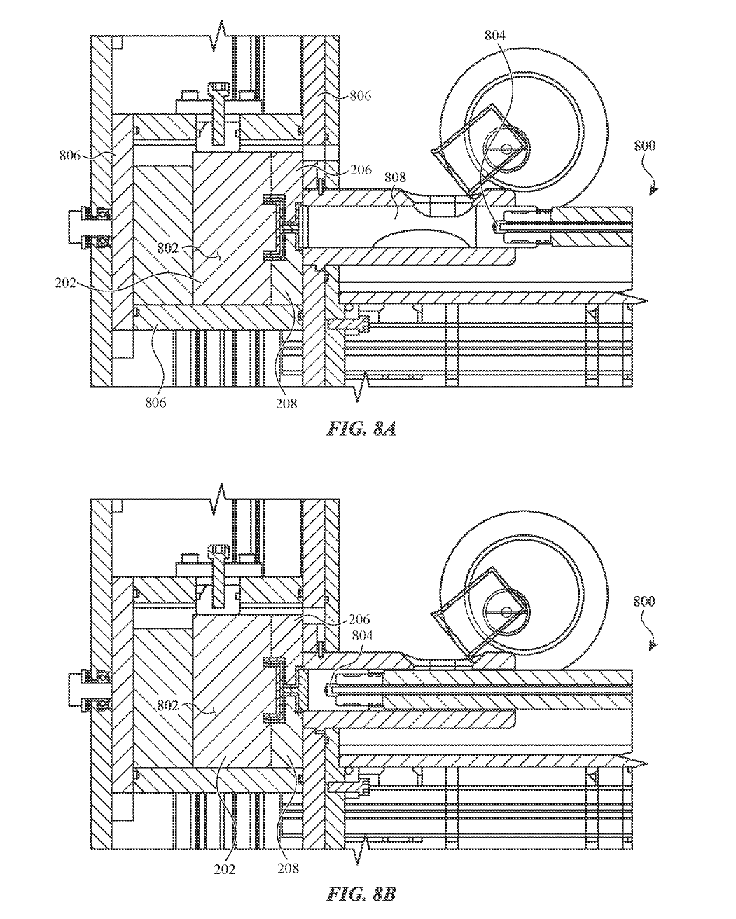

FIGS. 8A and 8B show two cross-sectional views of an illustrative casting machine 800 having the investment-diecasting mold 802 in accordance with embodiments herein. As discussed above, the hybrid investment-diecasting mold 802 has an outer 200 and inner 400 layers and defined cavity 403 for receiving melted or molten amorphous metal, so as to form a complex near-to-net shaped part 100. FIG. 8A shows amorphous metal prior to injection of into the investment-diecast mold. Various structural portions 806 are shown providing the support necessary for positioning the investment-diecasting mold. A piston 804 is poised to force the melted amorphous metal into the investment-diecasting mold with enough force to reach the entire mold cavity. A cavity 808 receives the molten amorphous alloy in sufficient amount to complete the desired part 100.

FIG. 8B shows the amorphous metal after injection into the investment-diecasting mold. Typical embodiments utilize a standard or conventional diecasting machine with an investment-diecasting mold positioned therein. The piston forces the molten amorphous alloy into the investment-diecasting mold, where it is quenched, to form the desired part.

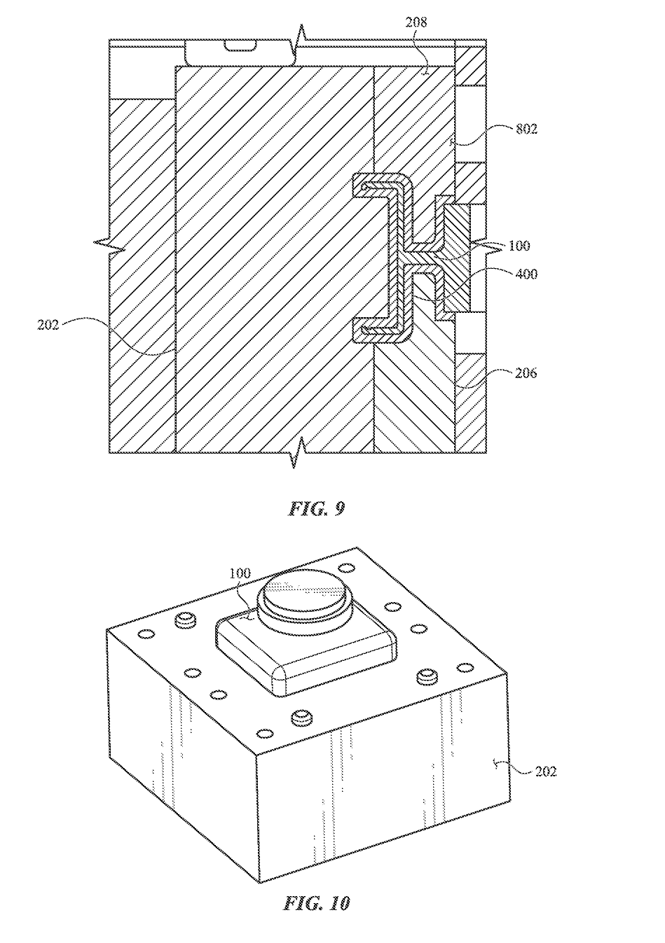

FIG. 9 shows an amorphous alloy filled investment-diecasting mold 802 in accordance with the disclosure herein. The cross-sectional view provides a view of the outer mold pieces 202, 206, 208 and inner investment layer 400. The formed amorphous alloy part 100 is formed by quenching of the alloy through the outer mold pieces.

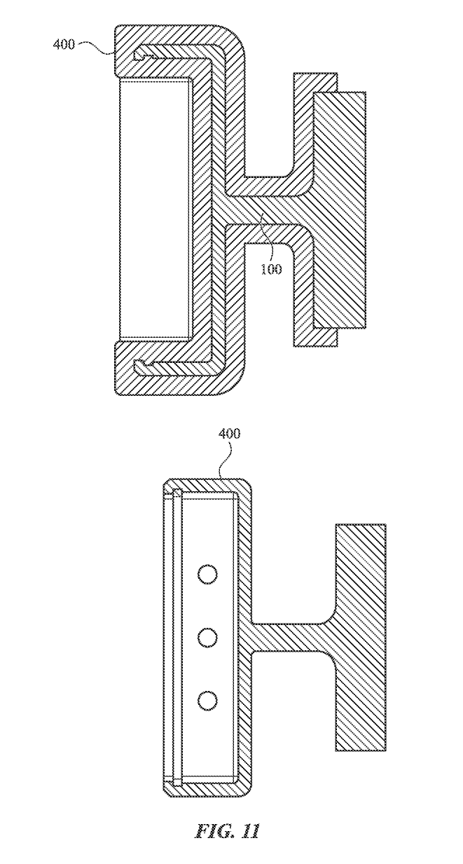

FIG. 10 provides a perspective view of removal of the bottom outer mold pieces (206 and 208—not shown in this Figure) from the amorphous alloy part 100. The outer mold is removed from the formed amorphous alloy part once the part is quenched. In some embodiments, the amorphous alloy part is substantially free of crystallinity. In other embodiments, the amorphous alloy part has less than 5% of the alloy in the crystalline phase.

As illustrated in FIG. 11, the inner investment mold 400 can be removed from part 100 either by extracting the part from the outer mold with the ceramic inner mold still attached and then removing the ceramic material, or by first removing the inner investment mold layer from the part in situ.

In some embodiments, the inner investment mold is dissolved off. Part removal, with or without the investment mold attached, can be accomplished from the outer mold via vibration or use of a pressure wash, for example. In typical cases the fabricated amorphous metal part is ready for its intended use, typically in a near-to-net shape. In some instances, a fabricated part may require additional processing, although the amount of processing will be smaller than a comparable piece prepared by standard diecasting techniques.

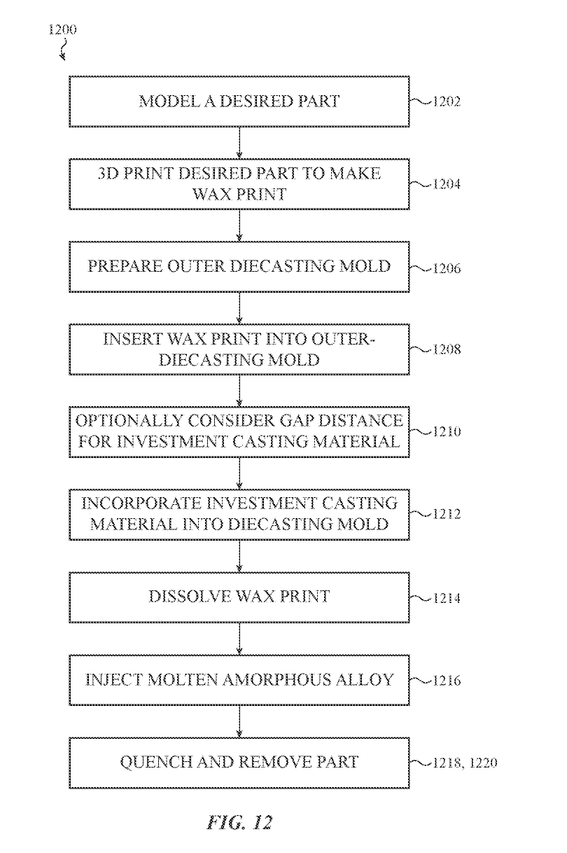

As shown in FIG. 12, embodiments herein also include methods for fabricating amorphous metal parts 1200. In some aspects the amorphous metal parts are formed in near-to-net shape. In operation 1202, a target part to be composed of amorphous metal is optionally identified, and a model of the part prepared. In operation 1204, a wax print is made from the model using 3D printing or other conventional technique 1204. In operation 1206, based on the size and shape of the proposed amorphous metal part, an appropriately sized outer diecasting mold is designed and prepared having a sufficiently large cavity for inclusion of the wax print and intended investment material layer. Outer molds are also prepared to include a sufficient amount of material to act as a heat sink for quenching the amount and thickness of amorphous metal for part formation.

In some embodiments, the outer diecasting mold assembly may also include cooling conduits throughout to facilitate quenching of the amorphous material. Fluids for use in the cooling conduits include water, brine, oil, NaOH and the like. Cooling conduits can be defined throughout the outer mold and are designed to maximize the cooling rate of desired amorphous metal parts.

In operation 1208, once the outer mold is prepared and in place, the wax print is positioned within the outer mold cavity. In operation 1210, a gap is defined between the wax print and the inner wall or surface of the outer mold where the gap corresponds to the thickness and position of the inner investment casting mold.

In operation 1212, the appropriately composed inner investment casting material is filled into the gap to form the two layer hybrid investment-diecasting mold of the disclosure. Note that the type of investment casting material and thickness of material are important for thermoconductivity. Investment casting material, for example ceramics, can be filled from the backside or through a hole in the wax print. Presence, thickness, an uniformity of the investment casting layer in the investment-diecasting mold is designed to maximize both utility of the investment layer and cost of the layer or the underlying outer diecasting mold. In some cases where little or no value is occasioned by the investment layer, the gap between the outer mold and desired part would not be present, and would only be present at portions where the underlying part or outer diecasting mold necessitate the layer.

In operation 1214, once the inner investment cast is set, the wax print can be dissolved out of the investment-diecasting mold (via steam or solvent, for example), leaving a precisely defined negative space for the desired part.

In operation 1216, the hybrid investment-diecasting mold may then be loaded onto a diecasting machine for injection molding of the appropriate amorphous alloy into the investment-diecasting mold. The molten amorphous alloy is injected into the hybrid investment-diecasting mold.

In operation 1218, the investment-diecasting mold quenches the amorphous alloy by the heat sink aspects of the outer mold and the thermoconductivity of the inner investment cast layer. In some embodiments, this includes use of flowing fluids through cooling conduits in the outer diecasting mold. In some embodiments, quenched amorphous alloy parts maintain the investment casting layer until removed via solvent.

In operation 1220, the investment-diecast amorphous alloy part can then be removed from the outer mold via vibration or under a pressure wash. In some aspects, the formed part is further processed using known techniques, but is typically in a near-to-net shape. The outer diecasting mold is then inspected for damage, and a determination made as to the durability of the mold. Typical hybrid molds herein provide a significant advantage, in that the outer mold can be re-used numerous times due to the protection afforded by the inner investment mold.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art that many modifications and variations are possible in view of the above teachings.

What is claimed is:

1. An investment-diecasting mold comprising:
an inner investment casting mold for defining a cavity, the cavity shaped as a negative imprint for at least a portion of a part; and
an outer diecasting mold, the outer diecasting mold encasing and operatively contacting the inner investment casting mold.

2. The investment-diecasting mold of claim 1, wherein the inner investment casting mold is composed of a thermally conductive ceramic material.

3. The investment-diecasting mold of claim 2 wherein the thermally conductive ceramic material is selected from the group consisting of alumina, silicon, nitride, and silicon nitride.

4. The investment-diecasting mold of claim 2, wherein the inner investment casting mold has a thickness of from about 1 mm and about 4 mm.

5. The investment-diecasting mold of claim 1, wherein the outer diecasting mold is composed of a material selected from the group consisting of steel, stainless steel, aluminum, copper, and brass.

6. The investment-diecasting mold of claim 5, wherein the outer diecasting mold has an appropriate mass to act as a heat sink for quenching parts made of amorphous metals.

7. The investment-diecasting mold of claim 6, wherein the outer diecasting mold defines one or more cooling conduits for inclusion of water, brine, NaOH or oil.

8. A method comprising:
filling a gap formed between a wax print and an outer diecasting mold with an investment casting material;
dissolving the wax print such that it leaves a cavity formed by the investment casting material;
injecting molten amorphous alloy into the cavity formed in the investment casting material thereby forming a desired part out of amorphous alloy in the shape of the wax print; and
dissolving the investment casting material from the part and removing the amorphous alloy part from the outer diecasting mold.

9. The method of claim 8, further comprising processing the amorphous alloy part after removal from the outer diecasting mold.

10. The method of claim 8, wherein the outer diecasting mold has sufficient mass and thermal conductivity to quench the desired part.

11. The method of claim 10 wherein the diecasting mold further defines cooling conduits for passing a fluid through to quench the desired part.

12. The method of claim 10 wherein the desired part is a housing for an electronic device.

13. The method of claim 12 wherein the electronic device is a mobile phone.

14. An electronic device comprising:
a housing composed of amorphous alloy;
a display positioned within the housing; and
a cover positioned over the display;
wherein the housing has:
a thickness of at least 0.1 mm; and
a near net shape having a geometric overhang and substantially free of surface defects.

15. The electronic device of claim 14 wherein the housing has a thickness of at least 0.3 mm.

16. The electronic device of claim 14, wherein the housing has a thickness of at least 0.5 mm.

17. The electronic device of claim 14, wherein the amorphous alloy is a BMG.

18. The electronic device of claim 14, wherein the electronic device is a wearable electronic device.

19. The electronic device of claim 14, wherein the electronic device is a mobile phone.

20. The electronic device of claim 14, wherein the near net shape housing does not require additional processing to form the geometric overhang.
